(19) United States
(12) Patent Application Publication
(10) Pub. No.: US 2013/0344626 A1
(43) Pub. Date: Dec. 26, 2013

(54) METHOD FOR MANUFACTURING SEMICONDUCTOR DEVICE, AND FILM FORMATION DEVICE

(71) Applicant: Sumitomo Electric Industries, Ltd., Osaka-shi (JP)

(72) Inventor: Ren Kimura, Osaka-shi (JP)

(73) Assignee: Sumitomo Electric Industries, Ltd., Osaka-shi (JP)

(21) Appl. No.: 13/894,106

(22) Filed: May 14, 2013

Related U.S. Application Data
(60) Provisional application No. 61/662,784, filed on Jun. 21, 2012.

(30) Foreign Application Priority Data
Jun. 21, 2012 (JP) 2012-139349

(51) Int. Cl. H01L 21/66

(52) U.S. Cl. CPC H01L 22/26
USPC 438/10; 118/712

(57) ABSTRACT

A semiconductor substrate having a surface is prepared. An electrical conductor film is formed on a region including the surface of the semiconductor substrate. The step of forming the electrical conductor film includes the steps of measuring, at a point of time when the electrical conductor film is partially formed, a characteristic related to at least one of alternating current loss and alternating current electrical conductivity of the electrical conductor film partially formed, and adjusting a film formation condition for forming the electrical conductor film based on the characteristic. Thereby, a surface roughness of the film being formed can be fed back to the film formation condition.

### BACKGROUND OF THE INVENTION

1. Field of the Invention

The present invention relates to a method for manufacturing a semiconductor device, and a film formation device, and in particular to a method for manufacturing a semiconductor device including the step of forming an electrical conductor film, and a film formation device for forming the electrical conductor film.

2. Description of the Background Art

Manufacturing of a semiconductor device generally involves formation of an electrical conductor film. Such film formation is required to be performed stably in mass production. In a film formation device of Japanese Patent Laying-Open No. 2010-236040, a thin film is formed in a film formation chamber, aside from a film formation sample. Further, the film formation device includes a physical quantity measurement element reading a physical quantity of the thin film being formed, a comparison portion comparing the physical quantity with a desired physical quantity, and a control portion controlling a film formation condition and the like based on a comparison result.

A simple method capable of using a surface roughness of a film being formed as a parameter to be fed back to a film formation condition has been previously unknown.

### SUMMARY OF THE INVENTION

The present invention has been made to solve the aforementioned problem, and one object of the present invention is to provide a method for manufacturing a semiconductor device capable of feeding back a surface roughness of a film being formed to a film formation condition, and a film formation device therefor.

A method for manufacturing a semiconductor device in accordance with the present invention includes the steps of preparing a semiconductor substrate having a surface, and forming an electrical conductor film on a region including the surface of the semiconductor substrate. The step of forming the electrical conductor film includes the steps of measuring, at a point of time when the electrical conductor film is partially formed, a characteristic related to at least one of alternating current loss and alternating current electrical conductivity of the electrical conductor film partially formed, and adjusting a film formation condition for forming the electrical conductor film based on the characteristic.

With the manufacturing method, a surface roughness of the electrical conductor film being formed can be fed back to the film formation condition. Thereby, a semiconductor device provided with an electrical conductor film having a desired surface roughness can be obtained.

Preferably, when the characteristic is measured, an alternating current having a frequency of not less than 1×10⁶ Hz and not more than 1×10¹⁵ Hz is applied to the electrical conductor film partially formed.

By using a frequency of not less than 1×10⁶ Hz, a surface roughness in RMS of not more than 10 μm, which is particularly useful in a typical method for manufacturing a semiconductor device, can be measured. Further, by using a frequency of not more than 1×10¹⁵ Hz, a measurement portion of a film formation device can be simplified, because the frequency is not excessively high.

The electrical conductor film may include a portion configured as a bonding pad for wire bonding.

Thereby, the bonding pad can have a desired surface roughness. It is noted that the bonding pad may be required to have a surface roughness of a certain degree or more in order to ensure bonding strength with a bonding wire.

The step of forming the electrical conductor film may be performed by forming an aluminum film.

Thereby, an aluminum film having a managed surface roughness can be formed. The aluminum film can be used, for example, as the bonding pad.

The step of measuring the characteristic may include the steps of applying an alternating current having a first frequency to the electrical conductor film partially formed, and applying an alternating current having a second frequency different from the first frequency to the electrical conductor film partially formed.

Thereby, the surface roughness can be measured with a higher accuracy or in a wider range.

A film formation device in accordance with the present invention includes a film formation portion, a measurement portion, and a control portion. The film formation portion is a portion for forming an electrical conductor film on a region including a surface of a semiconductor substrate. The measurement portion is a portion for measuring a characteristic related to at least one of alternating current loss and alternating current electrical conductivity and measuring a thickness of the electrical conductor film on the region. The control portion is a portion for adjusting a film formation condition of the film formation portion based on the characteristic.

With the film formation device, a surface roughness of the film being formed can be fed back to the film formation condition. Thereby, an electrical conductor film having a desired surface roughness can be formed.

As described above, according to the present invention, an electrical conductor film having a desired surface roughness can be formed.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross sectional view schematically showing a configuration of a film formation device in Embodiment 1 of the present invention.

FIG. 2 is a circuit diagram for schematically illustrating a measurement system of a measurement portion in FIG. 1.

FIG. 3 is a cross sectional view schematically showing a first step of a method for manufacturing a semiconductor device in Embodiment 1 of the present invention.

FIG. 4 is a cross sectional view schematically showing a second step of the method for manufacturing the semiconductor device in Embodiment 1 of the present invention.

FIG. 5 is a cross sectional view schematically showing a third step of the method for manufacturing the semiconductor device in Embodiment 1 of the present invention.

FIG. 6 is a partial cross sectional view schematically showing a configuration of a semiconductor device in Embodiment 2 of the present invention.

FIG. 7 is a partial cross sectional view schematically showing a tenth step of a method for manufacturing the semiconductor device of FIG. 6.

FIG. 8 is a partial cross sectional view schematically showing an eleventh step of the method for manufacturing the semiconductor device of FIG. 6.

FIG. 9 is a partial cross sectional view schematically showing a first step of the method for manufacturing the semiconductor device of FIG. 6.

FIG. 10 is a partial cross sectional view schematically showing a second step of the method for manufacturing the semiconductor device of FIG. 6.

FIG. 11 is a partial cross sectional view schematically showing a third step of the method for manufacturing the semiconductor device of FIG. 6.

FIG. 12 is a partial cross sectional view schematically showing a fourth step of the method for manufacturing the semiconductor device of FIG. 6.

FIG. 13 is a partial cross sectional view schematically showing a fifth step of the method for manufacturing the semiconductor device of FIG. 6.

FIG. 14 is a partial cross sectional view schematically showing a sixth step of the method for manufacturing the semiconductor device of FIG. 6.

FIG. 15 is a partial cross sectional view schematically showing a seventh step of the method for manufacturing the semiconductor device of FIG. 6.

FIG. 16 is a partial cross sectional view schematically showing an eighth step of the method for manufacturing the semiconductor device of FIG. 6.

FIG. 17 is a partial cross sectional view schematically showing a ninth step of the method for manufacturing the semiconductor device of FIG. 6.

### DESCRIPTION OF THE PREFERRED EMBODIMENTS

The following describes embodiments of the present invention with reference to the drawings. It should be noted that in the below-mentioned drawings, the same or corresponding portions are given the same reference characters and are not described repeatedly. Further, in the crystallographic description in the present specification, an individual orientation is represented by [ ], a group orientation is represented by < >, an individual plane is represented by ( ) and a group plane is represented by { }. In addition, a negative index is supposed to be crystallographically indicated by putting “−” (bar) above a numeral, but is indicated by putting the negative sign before the numeral in the present specification.

### Embodiment 1

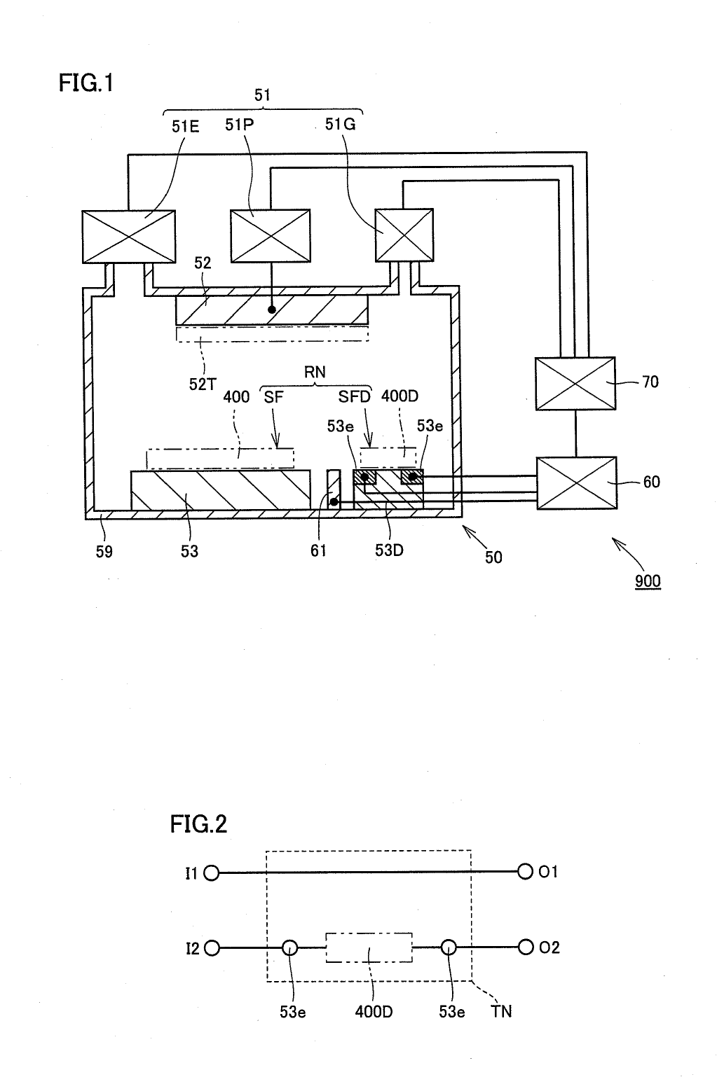

As shown in FIG. 1, a film formation device 900 in the present embodiment is a sputtering film formation device for forming an electrical conductor film. Here, the electrical conductor film refers to a film made of an electrical conductor, and the electrical conductor refers to a material having a conductivity of not less than 1×10⁻⁶ (S/m). The electrical conductor is preferably a conductor. Film formation device 900 has a film formation portion 50, a measurement portion 60, and a control portion 70.

Film formation portion 50 is a portion for forming the electrical conductor film on a region RN including a surface SF of a semiconductor substrate 400 and a surface SFD of a dummy 400D. Specifically, film formation portion 50 has a controlled portion 51, a target attachment portion 52, a substrate supporting portion 53, a dummy supporting portion 53D, and a container 59.

Controlled portion 51 enables film formation under a film formation condition having an externally controllable film formation parameter. Specifically, controlled portion 51 has a gas introduction portion 51G, an exhaust portion 51E, and a power source 51P. Gas introduction portion 51G is a portion for introducing a process gas into container 59. Gas introduction portion 51G has, for example, the type of the gas and the flow rate, as film formation parameters. Exhaust portion 51E is a portion for exhausting the gas from container 59, and has, for example, a valve and a pump. Exhaust portion 51E has, for example, the opening degree of the valve, as a film formation parameter. Power source 51P is a portion for supplying electric power to target attachment portion 52. Power source 51P has, for example, the value of the electric power, as a film formation parameter. Target attachment portion 52 is configured such that a sputtering target 52T is attached thereto.

Substrate supporting portion 53 is a portion for supporting semiconductor substrate 400 having surface SF. Substrate supporting portion 53 is, for example, a substrate stage provided with a chuck capable of fixing semiconductor substrate 400.

Dummy supporting portion 53D is a portion for supporting dummy 400D having surface SFD. Dummy supporting portion 53D has a pair of electrodes 53e apart from each other. Each of the pair of electrodes 53e is arranged to come into contact with dummy 400D when dummy 400D is supported.

Measurement portion 60 is a portion for measuring a characteristic related to at least one of alternating current loss and alternating current electrical conductivity on surface SFD of region RN. Further, measurement portion 60 may be able to measure a direct current characteristic on surface SFD of region RN. For these purposes, measurement portion 60 is electrically connected to the pair of electrodes 53e of dummy supporting portion 53D. Measurement portion 60 is, for example, an S parameter measurement system in an electric circuit TN (FIG. 2) having input terminals I1, I2 and output terminals O1, O2. Input terminal I1 and output terminal O1 are short-circuited to each other. Input terminal I2 is connected to one of the pair of electrodes 53e, and output terminal O2 is connected to the other of the pair of electrodes 53e. An S parameter can be measured, for example, with a network analyzer.

In addition, measurement portion 60 is also a portion for measuring the thickness of the electrical conductor film. For this purpose, measurement portion 60 may be electrically connected to a film thickness measurement portion 61. Film thickness measurement portion 61 is, for example, a crystal oscillator. It is noted that, when measurement portion 60 is configured to also measure a direct current as described above, the thickness of the electrical conductor film can be calculated from the result of the measurement, and thus film thickness measurement portion 61 can be omitted.

Control portion 70 is configured to control the film formation parameter of controlled portion 51 based on the characteristic measured by measurement portion 60. In other words, control portion 70 is configured to be able to adjust the film formation condition of film formation portion 50. Control portion 70 is, for example, a computer receiving information from measurement portion 60 and outputting information to controlled portion 51.

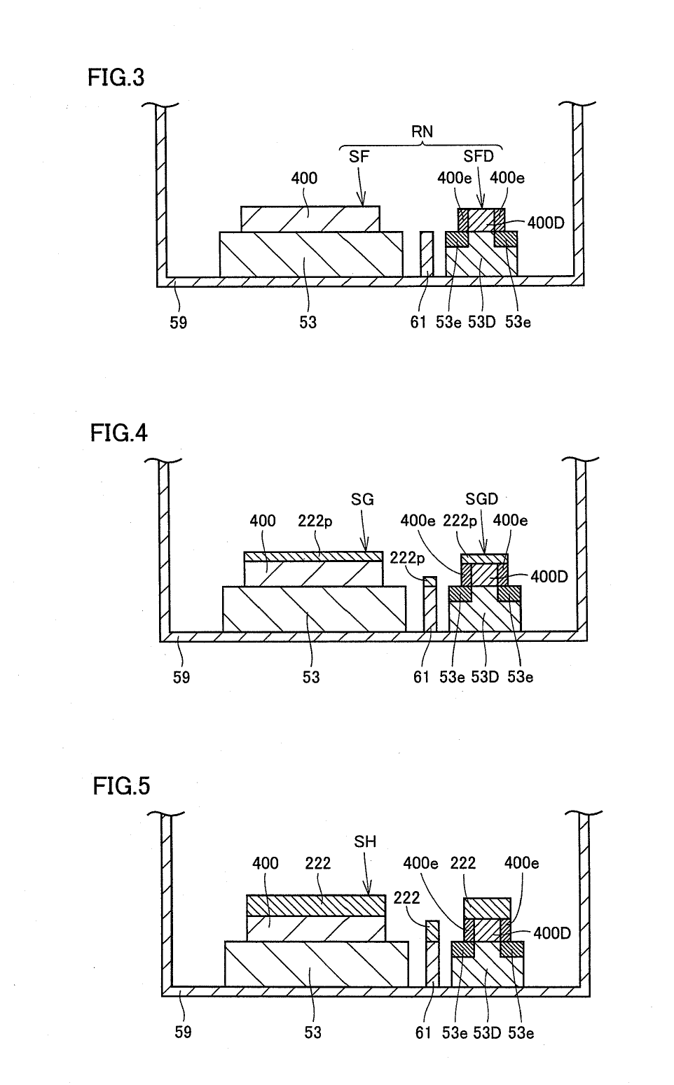

Next, a film formation method using film formation device 900 will be described with reference to FIGS. 3 to 5. It is noted that each of FIGS. 3 to 5 shows only a portion of film formation device 900 (FIG. 1). Further, this film formation method is applicable to a method for manufacturing a semiconductor device. Details of such application will be described in Embodiment 2.

Referring to FIG. 3, semiconductor substrate 400 having surface SF is prepared, and supported by substrate supporting portion 53. Further, dummy 400D is prepared, and supported by dummy supporting portion 53D. Dummy 400D has a pair of electrodes 400e apart from each other. One and the other of the pair of electrodes 400e are arranged to be able to come into contact with one and the other of the pair of electrodes 53e, respectively. In addition, each electrode 400e includes a portion in surface SFD.

Subsequently, after the step shown in FIG. 4, an electrical conductor film 222 (FIG. 5) is formed on region RN including surface SF of semiconductor substrate 400 and surface SFD of dummy 400D. Specifically, the step described below is performed.

For example, control portion 70 controls the film formation parameter of controlled portion 51 in accordance with a preprogrammed procedure to start sputtering of sputtering target 52T in a desired atmosphere. Thereby, formation of the electrical conductor film is started on region RN including surface SF of semiconductor substrate 400 and surface SFD of dummy 400D, as shown in FIG. 4. FIG. 4 shows an electrical conductor film 222p indicating electrical conductor film 222 (FIG. 5) at a point of time when it is partially formed (i.e., incomplete electrical conductor film 222). At this point of time, a characteristic related to at least one of alternating current loss and alternating current electrical conductivity of electrical conductor film 222p under a specific frequency is measured by measurement portion 60 (FIG. 1). Further, the film thickness of electrical conductor film 222p is measured by measurement portion 60. Based on the above characteristic and film thickness, a surface roughness of a surface SG of electrical conductor film 222p is estimated. A method for the estimation will be described below.

First, based on the above measured characteristic and film thickness, a conductivity σ_{C} of a portion of electrical conductor film 222p formed between the pair of electrodes 400e under the specific frequency is calculated. Thereby, the value of the following equation (1) can be obtained:

1/K_{W}²=σ_{C}/σ (1),

where σ is a conductivity as a physical property value inherent to a material for electrical conductor film 222p.

It is noted that the value of σ can be calculated from the film thickness and direct current characteristic measured by measurement portion 60. Alternatively, the value of σ may be dealt with as a known constant, and in this case, measurement of the direct current characteristic does not have to be performed.

On the other hand, the following equation (2) is formulated:

K_{W}=1+exp(−s/2h)^{1.6} (2),

where s is a skin depth in a skin effect, and h is a surface roughness (RMS) of a surface SGD (FIG. 4) of a portion of electrical conductor film 222p on dummy 400D. Skin depth s is expressed by the following equation (3):

s={2/(σ·ω·μ)}^{0.5} (3),

where ω is a frequency angular velocity and μ is a magnetic permeability. When electrical conductor film 222p is made of aluminum, s depends on frequency as indicated in Table 1 shown below.

TABLE 1

| Frequency (Hz) | Skin Depth (m) |
|---|---|
| 1 × 10¹ | 2.08981 × 10⁻² |
| 1 × 10² | 6.60855 × 10⁻³ |
| 1 × 10³ | 2.08981 × 10⁻³ |
| 1 × 10⁴ | 6.60855 × 10⁻⁴ |
| 1 × 10⁵ | 2.08981 × 10⁻⁴ |
| 1 × 10⁶ | 6.60855 × 10⁻⁵ |
| 1 × 10⁷ | 2.08981 × 10⁻⁵ |
| 1 × 10⁸ | 6.60855 × 10⁻⁶ |
| 1 × 10⁹ | 2.08981 × 10⁻⁶ |
| 1 × 10¹⁰ | 6.60855 × 10⁻⁷ |
| 1 × 10¹¹ | 2.08981 × 10⁻⁷ |
| 1 × 10¹² | 6.60855 × 10⁻⁸ |
| 1 × 10¹³ | 2.08981 × 10⁻⁸ |
| 1 × 10¹⁴ | 6.60855 × 10⁻⁹ |
| 1 × 10¹⁵ | 2.08981 × 10⁻⁹ |
| 1 × 10¹⁶ | 6.60855 × 10⁻¹⁰ |

From equation (2) and Table 1, the value of 1/K_{W}² corresponding to a combination of surface roughness (RMS) and frequency (f) is calculated as indicated in Table 2 shown below.

TABLE 2

| | RMS (m) | | | | | | | | | | |
|---|---|---|---|---|---|---|---|---|---|---|---|
| f (Hz) | 1 × 10⁻¹⁰ | 1 × 10⁻⁹ | 1 × 10⁻⁸ | 1 × 10⁻⁷ | 1 × 10⁻⁶ | 1 × 10⁻⁵ | 1 × 10⁻⁴ | 1 × 10⁻³ | 1 × 10⁻² | 1 × 10⁻¹ | 1 × 10⁻⁰ |
| 1 × 10¹ | 1.000000 | 1.000000 | 1.000000 | 1.000000 | 1.000000 | 1.000000 | 1.000000 | 1.000000 | 0.708664 | 0.293438 | 0.254197 |
| 1 × 10² | 1.000000 | 1.000000 | 1.000000 | 1.000000 | 1.000000 | 1.000000 | 1.000000 | 0.989961 | 0.395863 | 0.263389 | 0.251323 |
| 1 × 10³ | 1.000000 | 1.000000 | 1.000000 | 1.000000 | 1.000000 | 1.000000 | 1.000000 | 0.708664 | 0.293438 | 0.254197 | 0.250418 |
| 1 × 10⁴ | 1.000000 | 1.000000 | 1.000000 | 1.000000 | 1.000000 | 1.000000 | 0.989961 | 0.395863 | 0.263389 | 0.251323 | 0.250132 |
| 1 × 10⁵ | 1.000000 | 1.000000 | 1.000000 | 1.000000 | 1.000000 | 1.000000 | 0.708664 | 0.293438 | 0.254197 | 0.250418 | 0.250042 |
| 1 × 10⁶ | 1.000000 | 1.000000 | 1.000000 | 1.000000 | 1.000000 | 0.989961 | 0.395863 | 0.263389 | 0.251323 | 0.250132 | 0.250013 |
| 1 × 10⁷ | 1.000000 | 1.000000 | 1.000000 | 1.000000 | 1.000000 | 0.708664 | 0.293438 | 0.254197 | 0.250418 | 0.250042 | 0.250004 |
| 1 × 10⁸ | 1.000000 | 1.000000 | 1.000000 | 1.000000 | 0.989961 | 0.395863 | 0.263389 | 0.251323 | 0.250132 | 0.250013 | 0.250001 |
| 1 × 10⁹ | 1.000000 | 1.000000 | 1.000000 | 1.000000 | 0.708664 | 0.293438 | 0.254197 | 0.250418 | 0.250042 | 0.250004 | 0.250000 |
| 1 × 10¹⁰ | 1.000000 | 1.000000 | 1.000000 | 0.989961 | 0.395863 | 0.263389 | 0.251323 | 0.250132 | 0.250013 | 0.250001 | 0.250000 |
| 1 × 10¹¹ | 1.000000 | 1.000000 | 1.000000 | 0.708664 | 0.293438 | 0.254197 | 0.250418 | 0.250042 | 0.250004 | 0.250000 | 0.250000 |
| 1 × 10¹² | 1.000000 | 1.000000 | 0.989961 | 0.395863 | 0.263389 | 0.251323 | 0.250132 | 0.250013 | 0.250001 | 0.250000 | 0.250000 |
| 1 × 10¹³ | 1.000000 | 1.000000 | 0.708664 | 0.293438 | 0.254197 | 0.250418 | 0.250042 | 0.250004 | 0.250000 | 0.250000 | 0.250000 |
| 1 × 10¹⁴ | 1.000000 | 0.989961 | 0.395863 | 0.263389 | 0.251323 | 0.250132 | 0.250013 | 0.250001 | 0.250000 | 0.250000 | 0.250000 |
| 1 × 10¹⁵ | 1.000000 | 0.708664 | 0.293438 | 0.254197 | 0.250418 | 0.250042 | 0.250004 | 0.250000 | 0.250000 | 0.250000 | 0.250000 |
| 1 × 10¹⁶ | 0.989961 | 0.395863 | 0.263389 | 0.251323 | 0.250132 | 0.250013 | 0.250001 | 0.250000 | 0.250000 | 0.250000 | 0.250000 |

Based on Table 2, the surface roughness (RMS) of surface SGD of electrical conductor film 222p can be estimated from the measurement value of equation (1), that is, the value of 1/K_{W}², under the specific frequency. Since surface SG is formed simultaneously with surface SGD, it can be assumed that surface SG has a surface roughness substantially equal to that of surface SGD. Thus, the surface roughness of surface SG can be estimated.

Control portion 70 compares the surface roughness estimated as described above with a desired surface roughness. Then, the film formation condition is adjusted in accordance with a difference therebetween. Specifically, when the estimated surface roughness is too small, controlled portion 51 is controlled such that the surface roughness is further increased by subsequent film formation. In contrast, when the estimated surface roughness is too large, controlled portion 51 is controlled such that the surface roughness is further decreased by subsequent film formation. Thereby, electrical conductor film 222 (FIG. 5) provided with a surface SII having the desired surface roughness is eventually formed.

According to the present embodiment, the surface roughness of surface SG of electrical conductor film 222p (FIG. 4) being formed can be fed back to the film formation condition. Thereby, a semiconductor device including electrical conductor film 222 (FIG. 5) provided with surface SH having the desired surface roughness can be manufactured.

Preferably, when the characteristic is measured by measurement portion 60, an alternating current having a frequency of not less than 1×10⁶ Hz and not more than 1×10¹⁵ Hz is applied to electrical conductor film 222p. By using a frequency of not less than 1×10⁶ Hz, a surface roughness in RMS of not more than 10 μm, which is particularly useful in a typical method for manufacturing a semiconductor device, can be measured. Further, by using a frequency of not more than 1×10¹⁵ Hz, the measurement portion of film formation device 900 can be simplified, because the frequency is not excessively high.

Preferably, when the characteristic is measured by measurement portion 60, the steps of applying an alternating current having a first frequency to electrical conductor film 222p, and applying an alternating current having a second frequency different from the first frequency to electrical conductor film 222p are performed. Thereby, the surface roughness can be measured with a higher accuracy or in a wider range. Although the sputtering film formation device has been used as a film formation device in the present embodiment, the film formation device is not limited to a sputtering film formation device, and may be, for example, a deposition device, a plating device, or a CVD (Chemical Vapor Deposition) device.

Further, instead of using dummy 400D, a similar configuration may be provided on semiconductor substrate 400 as a TEG (Test Element Group). In this case, measurement portion 60 measures a characteristic related to at least one of alternating current loss and alternating current electrical conductivity, on surface SF instead of surface SFD.

### Embodiment 2

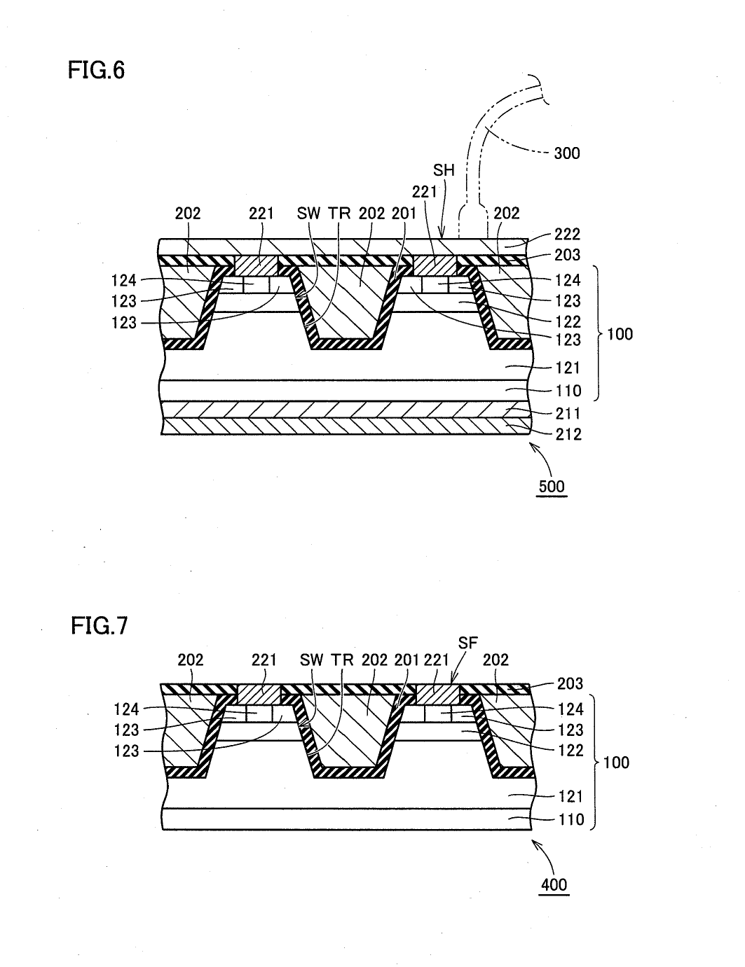

As shown in FIG. 6, a vertical-type MOSFET 500 (semiconductor device) in the present embodiment has an epitaxial substrate 100, a gate oxide film 201 (gate insulating film), a gate electrode 202, an interlayer insulating film 203, a source electrode 221, a drain electrode 211, a source wire 222 (electrical conductor film), and a protective electrode 212. Source wire 222 is configured such that a bonding wire 300 can be bonded on surface SH thereof. In other words, source wire 222 includes a portion configured as a bonding pad for wire bonding. Source wire 222 is preferably an aluminum film.

Epitaxial substrate 100 has a single crystal substrate 110, and an epitaxial layer provided thereon. Single crystal substrate 110 has n type (a first conductivity type). The epitaxial layer has an n⁻ layer 121 (a first layer), a p type body layer 122 (a second layer), an n region 123 (a third layer), and a contact region 124. N⁻ layer 121 has n type (the first conductivity type). N⁻ layer 121 has a donor concentration lower than that of single crystal substrate 110. P type body layer 122 is provided on n⁻ layer 121, and has p type (a second conductivity type). N region 123 is provided on p type body layer 122. Contact region 124 has p type. Contact region 124 is formed on a portion of p type body layer 122 to connect to p type body layer 122.

Epitaxial substrate 100 has a trench TR which penetrates n region 123 and p type body layer 122 and reaches n⁻ layer 121. Trench TR has side walls each having a surface SW. Surface SW includes a channel surface on p type body layer 122.

Gate oxide film 201 covers trench TR. Specifically, gate oxide film 201 is provided on surfaces SW and a bottom portion of trench TR. Gate oxide film 201 extends over an upper surface of n region 123. Gate electrode 202 is provided on gate oxide film 201 to fill the inside of trench TR. Gate electrode 202 faces surface SW of p type body layer 122 with gate oxide film 201 interposed therebetween. An upper surface of gate electrode 202 has a height substantially identical to that of a portion of gate oxide film 201 located over the upper surface of n region 123. Interlayer insulating film 203 is provided to cover the portion of gate oxide film 201 extending over the upper surface of n region 123, and gate electrode 202.

Source electrode 221 is in contact with each of contact region 124 and n region 123. Source wire 222 is in contact with source electrode 221, and extends on an upper surface of interlayer insulating film 203. Drain electrode 211 is an ohmic electrode provided on a back surface of single crystal substrate 110 opposite to its main surface provided with if layer 121. Protective electrode 212 is provided on drain electrode 211.

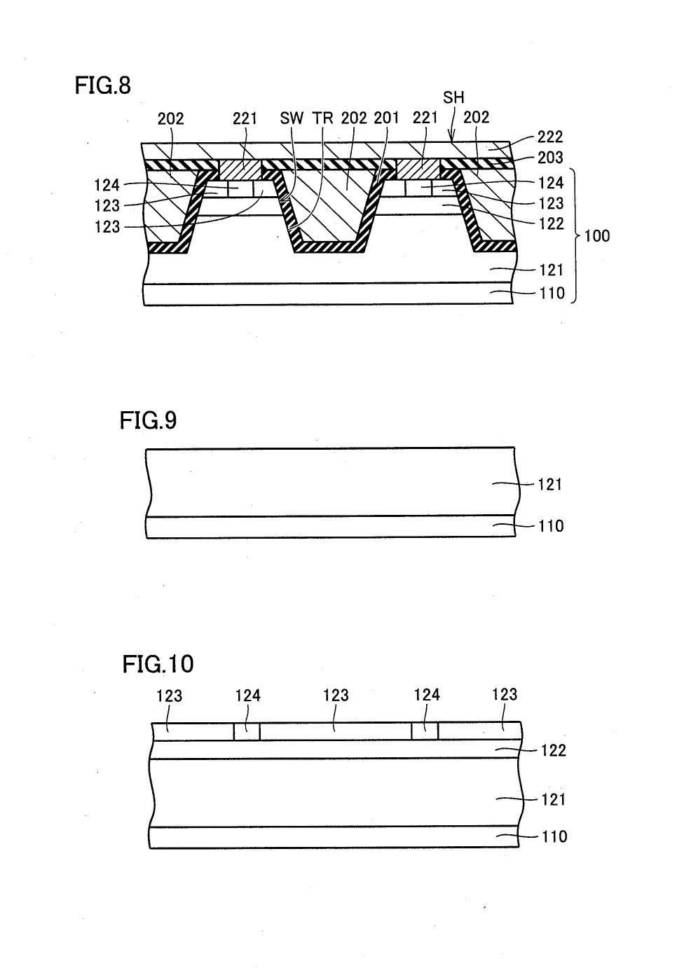

Next, a method for manufacturing MOSFET 500 will be described. Referring to FIG. 7, semiconductor substrate 400 is prepared by a method described later. Semiconductor substrate 400 has surface SF formed of interlayer insulating film 203 and source electrode 221. Further referring to FIG. 8, source wire 222 having surface SH is formed on surface SF by the film formation method described in Embodiment 1. Referring to FIG. 6 again, drain electrode 211 and protective electrode 212 are formed, and thereby MOSFET 500 is obtained.

According to the present embodiment, the bonding pad formed of surface SH of source wire 222 can have a desired surface roughness. It is noted that the bonding pad may be required to have a surface roughness of a certain degree or more in order to ensure bonding strength with bonding wire 300. However, if the surface roughness is extremely high, bonding strength may be decreased conversely due to formation of voids between bonding wire 300 and the bonding pad. Thus, from the viewpoint of bonding strength, surface SH of source wire 222 may be required to have a surface roughness of an approximately predetermined value.

Next, a method performed to obtain semiconductor substrate 400 (FIG. 7) will be described below, taking an exemplary case where the MOSFET (FIG. 6) is a silicon carbide semiconductor device.

As shown in FIG. 9, n⁻ layer 121 is formed by epitaxial growth of silicon carbide on single crystal substrate 110 made of silicon carbide. The epitaxial growth can be performed by a CVD (Chemical Vapor Deposition) method which uses, for example, a mixed gas of silane (SiH₄) and propane (C₃H₈) as a source gas, and uses, for example, hydrogen gas (H₂) as a carrier gas. On this occasion, it is preferable to introduce, for example, nitrogen (N) or phosphorus (P), as an impurity having n type conductivity.

As shown in FIG. 10, ion implantation is performed on an upper surface of n⁻ layer 121 to form p type body layer 122, n region 123, and contact region 124. In the ion implantation for forming p type body layer 122 and contact region 124, ions of an impurity for imparting p type, such as aluminum (Al), are implanted. In the ion implantation for forming n region 123, ions of an impurity for imparting n type, such as phosphorus (P), are implanted. It is noted that epitaxial growth may be used instead of ion implantation.

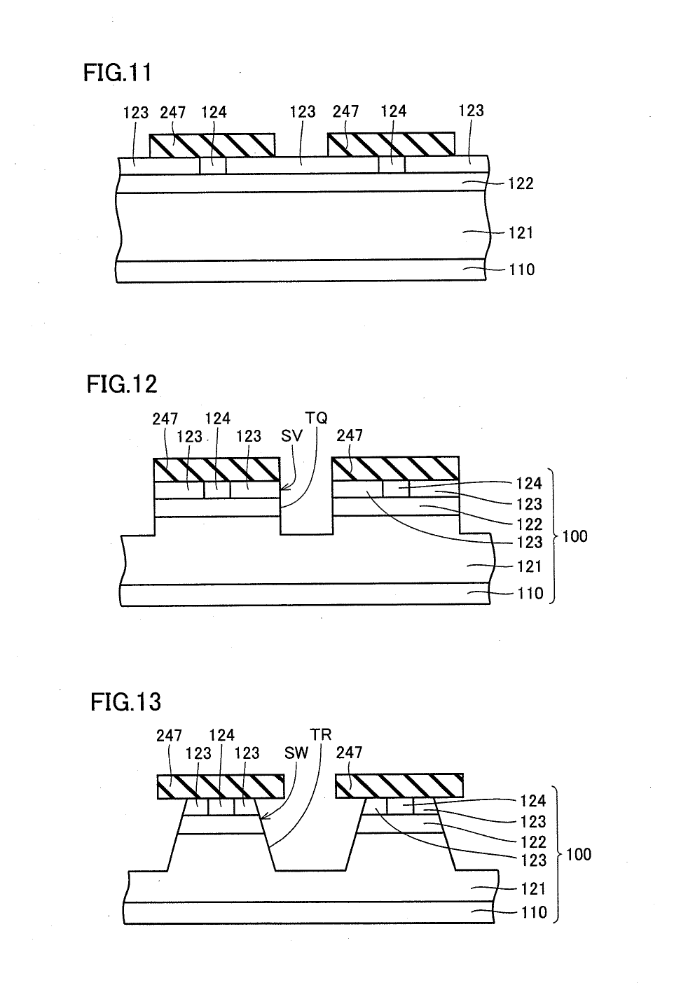

As shown in FIG. 11, a mask layer 247 having an opening is formed on a surface formed of n region 123 and contact region 124. As mask layer 247, for example, an insulating film such as a silicon oxide film can be used. The opening is formed at a position corresponding to the position of trench TR (FIG. 6).

As shown in FIG. 12, n region 123, p type body layer 122, and a portion of n⁻ layer 121 are removed by etching at the opening in mask layer 247. As a method for the etching, for example, Reactive Ion Etching (RIE), in particular, Induction Coupled Plasma (ICP) RIE, can be used. Specifically, ICP-RIE which uses, for example, SF₆ or a mixed gas of SF₆ and O₂ as a reactive gas can be used. By such etching, a concave portion TQ with side walls each having an inner surface SV substantially perpendicular to the main surface of single crystal substrate 110 can be formed in a region where trench TR (FIG. 6) is to be formed.

Subsequently, thermal etching is performed on epitaxial substrate 100 at inner surfaces SV of concave portion TQ. The thermal etching can be performed by heating epitaxial substrate 100 in an atmosphere containing a reactive gas having, for example, at least one or more types of halogen atoms. The at least one or more types of halogen atoms include at least one of chlorine (Cl) atoms and fluorine (F) atoms. The atmosphere is, for example, Cl₂, BCL₃, SF₆, or CF₄. The thermal etching is performed, for example, using a mixed gas of chlorine gas and oxygen gas as a reactive gas, at a thermal treatment temperature of not less than 700° C. and not more than 1000° C.

As shown in FIG. 13, trench TR is formed by the thermal etching. On this occasion, surface SW having portions respectively formed of n⁻ layer 121, p type body layer 122, and n region 123 is formed as the side wall of trench TR. On surface SW, a specific crystal plane can be spontaneously formed.

It is noted that the reactive gas may contain a carrier gas, in addition to chlorine gas and oxygen gas described above. As the carrier gas, for example, nitrogen (N₂) gas, argon gas, helium gas, or the like can be used. When the thermal treatment temperature is set to not less than 700° C. and not more than 1000° C. as described above, the rate of etching SiC is, for example, about 70 μm/hour. Further, in this case, mask layer 247 made of silicon oxide is substantially not etched during etching of SiC due to an extremely high selectivity with respect to SiC.

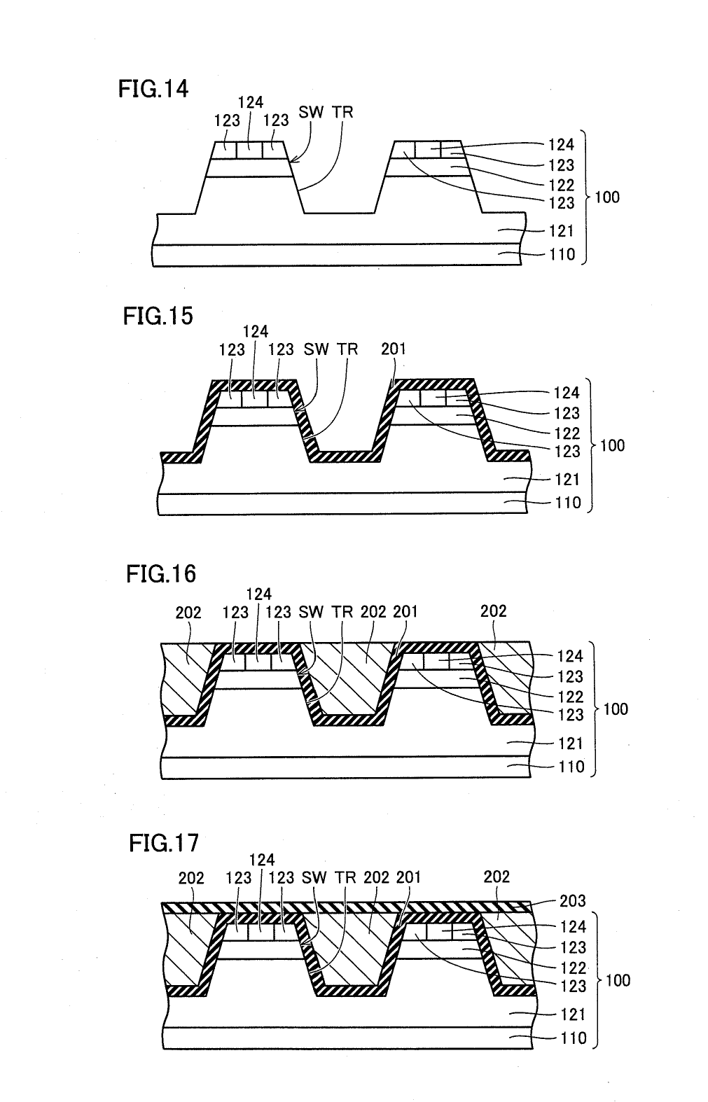

Subsequently, mask layer 247 is removed by an arbitrary method such as etching (FIG. 14). Further, activation annealing is performed to activate the impurities implanted by the ion implantation.

As shown in FIG. 15, gate oxide film 201 is formed on a surface including surfaces SW as the side walls and the bottom portion of trench TR. Gate oxide film 201 is obtained, for example, by thermally oxidizing the epitaxial layer made of silicon carbide.

As shown in FIG. 16, gate electrode 202 is formed to fill a region inside trench TR with gate oxide film 201 interposed therebetween. Formation of gate electrode 202 can be performed, for example, by formation of a conductor film and CMP (Chemical Mechanical Polishing).

As shown in FIG. 17, interlayer insulating film 203 is formed on gate electrode 202 and gate oxide film 201 to cover an exposed surface of gate electrode 202. Referring to FIG. 7 again, etching is performed to form an opening in interlayer insulating film 203 and gate oxide film 201. Through the opening, each of n region 123 and contact region 124 is exposed at an upper surface of a mesa structure. Then, source electrode 221 which comes into contact with each of n region 123 and contact region 124 is formed on the upper surface of the mesa structure. Thereby, semiconductor substrate 400 is obtained.

It is noted that the semiconductor device may be a MISFET (Metal Insulator Semiconductor Field Effect Transistor) other than a MOSFET. Further, the semiconductor device is not limited to a MISFET, and may be, for example, an IGBT (Insulated Gate Bipolar Transistor). Furthermore, the semiconductor device is not limited to a transistor, and may be, for example, a diode. In addition, the semiconductor device is not limited to a trench-type semiconductor device, and may be, for example, a planar-type semiconductor device. Moreover, the semiconductor device is not limited to a vertical-type semiconductor device, and may be, for example, a horizontal-type semiconductor device.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A method for manufacturing a semiconductor device, comprising the steps of:
preparing a semiconductor substrate having a surface; and
forming an electrical conductor film on a region including said surface of said semiconductor substrate,
the step of forming said electrical conductor film including the steps of
measuring, at a point of time when said electrical conductor film is partially formed, a characteristic related to at least one of alternating current loss and alternating current electrical conductivity of said electrical conductor film partially formed, and
adjusting a film formation condition for forming said electrical conductor film based on said characteristic.

2. The method for manufacturing the semiconductor device according to claim 1, wherein the step of measuring said characteristic includes the step of applying an alternating current having a frequency of not less than 1×10⁶ Hz and not more than 1×10¹⁵ Hz to said electrical conductor film partially formed.

3. The method for manufacturing the semiconductor device according to claim 1, wherein said electrical conductor film includes a portion configured as a bonding pad for wire bonding.

4. The method for manufacturing the semiconductor device according to claim 1, wherein the step of forming said electrical conductor film is performed by forming an aluminum film.

5. The method for manufacturing the semiconductor device according to claim 1, wherein the step of measuring said characteristic includes the steps of applying an alternating current having a first frequency to said electrical conductor film partially formed, and applying an alternating current having a second frequency different from the first frequency to said electrical conductor film partially formed.

6. A film formation device, comprising:
a film formation portion for forming an electrical conductor film on a region including a surface of a semiconductor substrate;
a measurement portion for measuring a characteristic related to at least one of alternating current loss and alternating current electrical conductivity and measuring a thickness of the electrical conductor film on said region; and
a control portion for adjusting a film formation condition of said film formation portion based on said characteristic.
